(19) United States
(12) Patent Application Publication
(10) Pub. No.: US 2007/0229269 A1
(43) Pub. Date: Oct. 4, 2007

(54) SYSTEM AND METHOD FOR MITIGATING INTERFERENCE BY RADIO FREQUENCY IDENTIFICATION AND ELECTRONIC ARTICLE SURVEILLANCE SYSTEMS WITH IMPLANTABLE CARDIAC DEVICES

(75) Inventor: Robert A. Morris, Oakridge, NC (US)

Correspondence Address: SEED INTELLECTUAL PROPERTY LAW GROUP PLLC, 701 FIFTH AVENUE, SUITE 5400, SEATTLE, WA, 98104-7092, US

(73) Assignee: INTERMEC IP CORP., Everett, WA (US)

(21) Appl. No.: 11/695,521

(22) Filed: Apr. 2, 2007

Related U.S. Application Data
(60) Provisional application No. 60/789,180, filed on Apr. 3, 2006.

(51) Int. Cl. G08B 13/14; G08B 21/00; G01R 13/00

(52) U.S. Cl. 340/572.1; 340/679; 702/66

(57) ABSTRACT

A radio frequency identification (RFID) system includes a tag reader configured to interrogate RFID tags in repeated transmission pulses, and a monitor module configured to monitor a transmission pulse rate of the RFID. When a pulse rate falling within a selected frequency range is detected, the monitor module is configured to modify the pulse rate to produce a transmission pulse rate that falls outside of the selected frequency range. Modification may include, for example, any of shortening an off-period between transmission pulses, shortening the transmission pulses, and introducing single electromagnetic spikes between transmission pulses. The monitor module may also be configured to interrupt operation of the system upon detection of a pulse rate falling within the selected frequency range, or to produce a signal indicating a detected pulse rate falling within the selected frequency range. The system may include a plurality of tag readers configured to interrogate RFID tags sequentially.

### CROSS-REFERENCE TO RELATED APPLICATION

This application claims the benefit of U.S. Provisional Patent Application No. 60/789,180 filed Apr. 3, 2006, where this provisional application is incorporated herein by reference in its entirety.

### BACKGROUND OF THE INVENTION

1. Field of the Invention

The present disclosure relates in general to automatic data collection (ADC) systems, and in particular, to signals produced by radio frequency identification (RFID) systems employing tags and interrogators or readers, and/or electronic article surveillance (EAS) systems.

2. Description of the Related Art

Electronic article surveillance (EAS) systems are found in a growing number of businesses, especially in the retail sector. A typical EAS system includes tags located on articles of interest and detectors strategically located, such as near exits of a business, such that a tag passing near a detector causes the detector to signal the presence of the tag.

A detector includes a transmitter and a receiver. Generally, the transmitter and receiver are in separate units positioned such that an individual must pass between them to exit the business. An EAS tag operates by interfering with, or resonating with, a transmitted signal when the EAS tag is brought into close proximity with the detector. The receiver detects the interference or resonance and indicates the presence of the tag. Such systems are typically used in retail establishments, where the tags are placed on merchandise and a transmitter and receiver are placed at the exit to prevent unauthorized removal of articles from the establishment. Apart from indicating the presence of an operational tag within range of the transmitter and receiver, no other information is transmitted.

Radio frequency identification (RFID) is a technology that is related to EAS technology. Like EAS systems, RFID systems utilize tags that can be applied to an article and later detected by radio frequency systems. However, there are significant differences, as well. In contrast to EAS technology, RFID systems can access a great deal of information related to individual tags.

RFID systems typically employ one or more interrogators to communicate with one or more RFID tags using electromagnetic signals in the radio, microwave or other portions of the electromagnetic spectrum which will be generically referred to herein as radio frequency or RF signals.

The RFID interrogator typically employs one or more radios in the form of receivers, transmitters or transceivers coupled to one or more antennas. At least one of the radios is operable to cause at least one of the antennas to emit an electromagnetic interrogation signal in a particular range of frequencies or wavelengths. At least one of the radios is operable to receive an electromagnetic return signal in a particular range of frequencies or wavelengths detected by at least one of the antennas. The frequency or wavelength of the interrogation signal may be different from the frequency or wavelength of the return signal, but is selected to match the operational characteristics of the RFID tags.

The RFID tags typically include an antenna and a memory. The memory may be implemented in an integrated circuit. The memory may be read only memory, or may be memory which can be repeatedly written. The RFID tag may also include logic, which may also be implemented in an integrated circuit. The logic may implement a variety of functions, for example security or password authentication, or encryption. Some RFID tags carry a discrete power device, and are commonly referred to as active tags, while other RFID tags derive power from the interrogation signal and are commonly referred to as passive tags.

In recent years, medical technology has been the subject of continuing and accelerating development. For example, implantable cardiac devices (ICD) for monitoring and responding to cardiac events are now in common use. These devices are generally configured to detect and correct cardiac arrhythmias, and are grouped into two general categories: implantable pacemakers and implantable defibrillators. In both cases, extremely sensitive probes placed in or near the heart muscle detect the electrical impulses that accompany muscle contraction. The ICD is generally implanted at the patient's chest under the skin, and thin wire leads connect the probes to the device.

Implantable pacemakers are designed generally to detect bradyarrhythmias-abnormally slow heart beats. When such a malfunction is detected, the pacemaker provides an electrical impulse, via one or more wires implanted directly into the heart muscle, at a normal heart rhythm to prompt the heart to return to a normal beat pattern. As long as a pacemaker detects a heartbeat pattern that is above a selected threshold, it will remain inactive.

Implantable defibrillators are configured to detect and respond to tachyarrhythmias-abnormally fast heart beat patterns. The term also encompasses fibrillation, which is an ineffectual fluttering of the heart muscle. During a tachyarrhythmia, the heart beats in a fast, sometimes uncoordinated manner, such that the ability of the heart to pump blood is diminished to a greater or lesser degree. When a defibrillator detects such an event, it may be programmed to respond with an electric shock delivered to the heart muscle. The shock is intended to interrupt an abnormal beat pattern and allow the heart to return to a normal pattern. The intensity of the electric shock is selected, at least in part, in response to the severity or type of the detected tachyarrhythmia. At higher levels of intensity this electric shock may be extremely painful to the patient.

Implantable defibrillators are sensitive to electrical signals occurring within a selected range of frequencies. For example, on the one hand, a defibrillator is designed to ignore signals below a low threshold frequency as indicating a normal heartbeat, and on the other hand, to ignore signals above a high threshold frequency as being attributable to normal skeletal-muscle electrical activity. Electromagnetic interference has been an area of general concern with implantable defibrillators and pacemakers, especially interference that occurs below 100 Hz, and more especially below 10-30 Hz.

Often, ICD's are configured to monitor an abnormal condition for several seconds (e.g., 10 seconds) or for a predetermined number of heartbeats, before corrective action is initiated. If the abnormal condition does not continue uninterrupted beyond the selected threshold, no action is initiated. For this reason, sources of interference that are transitory generally do not have a serious impact on a patient carrying an ICD.

However, with increasing use of implantable cardiac devices, reports of interference with such devices have also increased. It will be recognized that, in order to monitor electrical activity within a heart muscle, implantable cardiac devices must have a high degree of sensitivity. In many cases, the electric wires or probes can function as antennae to receive electromagnetic signals from outside the body. If these electromagnetic signals occur at frequencies that fall within the ranges of frequencies that these devices are configured to detect, malfunction of these devices may occur. For example, recent studies have determined a potential for interference from devices such as cell phones, slot machines, remote control toys, and EAS equipment.

Electromagnetic radiation from such electronic devices can interfere with the operation of an implanted cardiac device in one of two ways. First, electromagnetic radiation from such a device can mimic a normal heart rhythm, thus preventing the implanted device from responding to an abnormal condition. Second, the external electronic device can produce a signal that mimics an abnormal heart rhythm, prompting the implanted device to respond to a nonexistent cardiac event.

The term frequency may lead to confusion. Since the operating frequency of an RFID reader (e.g., 915 MHz) may be well outside of the frequency range of normal electrical cardiac activity, one might incorrectly assume that a particular reader will not provoke the types of interference described above. However, one must distinguish between the RFID reader's carrier frequency and the modulation frequency applied to the carrier. The modulation frequency may also be referred to as the pulse repetition rate.

The carrier frequency is generally in the range commonly referred to as radio frequency or simply RF. RF is further subdivided into bands: Low Frequency (LF), Medium Frequency (MF), High Frequency (HF), Very High Frequency (VHF), Ultra High Frequency (UHF), and Extremely High Frequency (EHF). The EHF range is more often called Microwaves. RFID tags and readers typically operate using carrier frequencies in the HF through microwave range.

A carrier frequency is a sinusoidal oscillation at a single frequency. Information can be added to the carrier by changing its amplitude, frequency, and/or phase. This process is called modulation. One common form of modulation used with RFID tag readers is simple on/off keying of the carrier. This is a form of amplitude modulation were the amplitude changes from 0% to 100%. When the signal is received, the information is recovered by the process of de-modulation, also referred to as detection. For amplitude modulated signals, any non-linear electronic device in the receiving circuit may serve as a detector through the process of rectification (conversion of AC to DC).

Modern pacemakers and ICDs typically are enclosed in a metal case and include filtering to prevent RF energy from entering the enclosure. The filter rejects the RF energy by reflecting it. The filters are quite effective at reflecting RF energy. However, if the incident RF energy is quite strong, such as when the device wearer is very close to a reader's antenna; sufficient RF energy may pass through the filter to allow unwanted demodulation inside the device. If the characteristics of the de-modulated signal mimic the cardiac signals, unintended operation of the medical device may result. Another possibility exists were the demodulation process takes place inside the body but outside of the pacemaker's or ICD's enclosure. In this case, the filter will not be effective at eliminating the unwanted signal. Such demodulation (due to rectification of the RF energy) may occur at the junction between the ICD electrode and the body tissue or in portions of the body tissue itself.

Thus, even though the operating frequency of the RFID tag reader is in the UHF or microwave region and would be reduced or rejected by the pacemaker's filter, interference is possible if the modulation is within the pass band of the ICD.

In a report in the New England Journal of Medicine (Interference with an Implantable Defibrillator by an Electronic Anti-theft Surveillance Device, Peter A. Santucci, et al., Nov. 5, 1998) a case of interference is detailed and analyzed. The report describes a case in which a patient is browsing at a magazine rack and stands very close to the transmitter of an electronic surveillance device located at the exit of a retail establishment. Electromagnetic pulses from the transmitter are detected by an implanted defibrillator worn by the patient, and interpreted as a fibrillation. The defibrillator responds by administering a series of powerful shocks to the patient's heart in an attempt to restore normal rhythm. The patient is incapacitated by the repeated shocks, and is unable to take any useful action in response. These shocks continue until a bystander pulls the patient from his position near the transmitter, at which time the defibrillator returns to normal operation.

The report proceeds to note several important concerns related to such occurrences. Apart from the physical discomfort and psychological effects of multiple shocks, it is possible that such shocks can induce cardiac ischemia in susceptible patients. Additionally, it is possible for the defibrillator to exhaust its available energy, rendering it unable to convert a true tachyarrhythmia to normal rhythm.

To reduce the danger of the occurrence of such events, the report recommends several measures, including educating patients with respect to the dangers of such equipment, and keeping merchandise some distance away from electronic surveillance equipment to prevent prolonged exposure of browsing customers.

Other publications that include information on ICD's include the following, which are incorporated herein by reference, in their entireties:

UpToDate.com Patient Information: Pacemakers, Brian Olshansky, M. D., et al., Oct. 12, 2004; New England Journal of Medicine Implantable Cardioverter-Defibrillators, John P. DiMarco, M.D., Ph.D., Nov. 6, 2003; and The Lancet The Implantable Cardioverter Defibrillator, Michael Gilkson, et al., Apr. 7, 2001.

For many pacemaker wearers, the pacemaker is required to be active only for brief periods of time. For example, once per week a cardiac episode may cause the heart rate to fall abnormally low, causing the patient to faint. The pacemaker will take over during such an episode and keep the heart beating at a safe rate. However, in many cases the underlying medical pathology eventually progresses to the point were the patient becomes pacemaker dependant. In such cases, if the pacemaker were to be inhibited from pacing by external interference that it interpreted as normal cardiac activity the result could be death.

### BRIEF SUMMARY OF THE INVENTION

According to one embodiment, a radio frequency identification (RFID) system comprises an RFID tag reader configured to interrogate RFID tags in repeated transmission pulses, each of the pulses comprising a plurality of signal cycles at an operating frequency, the system also including a monitor module configured to monitor a transmission pulse rate of the RFID tag reader and detect a pulse rate falling within a selected frequency range. The monitor module may be, for example, a software module of a controller of the RFID system, a component of the RFID tag reader, or a dedicated circuit configured for that purpose.

When a pulse rate falling within the selected frequency range is detected, the monitor module is configured to modify the pulse rate to produce a transmission pulse rate that falls outside of the selected frequency range. Modification of the pulse rate may include any of, for example, shortening an off-period between transmission pulses, shortening the transmission pulses, and introducing single electromagnetic spikes between transmission pulses. The monitor module may also be configured to interrupt operation of the RFID system upon detection of a pulse rate falling within the selected frequency range, or to produce a signal indicating a detected pulse rate falling within the selected frequency range.

According to an embodiment, the RFID system comprises a plurality of RFID tag readers, including the RFID tag reader, the plurality of RFID tag readers configured to interrogate RFID tags sequentially. The transmission pulse rate is then equal to a total pulse rate of the RFID system divided by the number of the plurality of RFID tag readers.

Various methods of operation are provided in accordance with respective embodiments of the invention.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

FIG. 1 is a top plan view showing a radio frequency identification tag according to one illustrated embodiment.

FIG. 2 is a schematic view showing a radio frequency identification system according to one illustrated embodiment.

FIG. 3 is a flow chart illustrating a method useful in setting up a radio frequency identification system according to one illustrated embodiment.

FIG. 4 is a flow chart illustrating a method useful in setting up a radio frequency identification system according to another illustrated embodiment.

### DETAILED DESCRIPTION OF THE INVENTION

In the following description, certain specific details are set forth in order to provide a thorough understanding of various embodiments of the invention. However, one skilled in the art will understand that the invention may be practiced without these details.

Unless the context requires otherwise, throughout the specification and claims which follow, the word “comprise” and variations thereof, such as, “comprises” and “comprising” are to be construed in an open, inclusive sense, that is, as “including, but not limited to.”

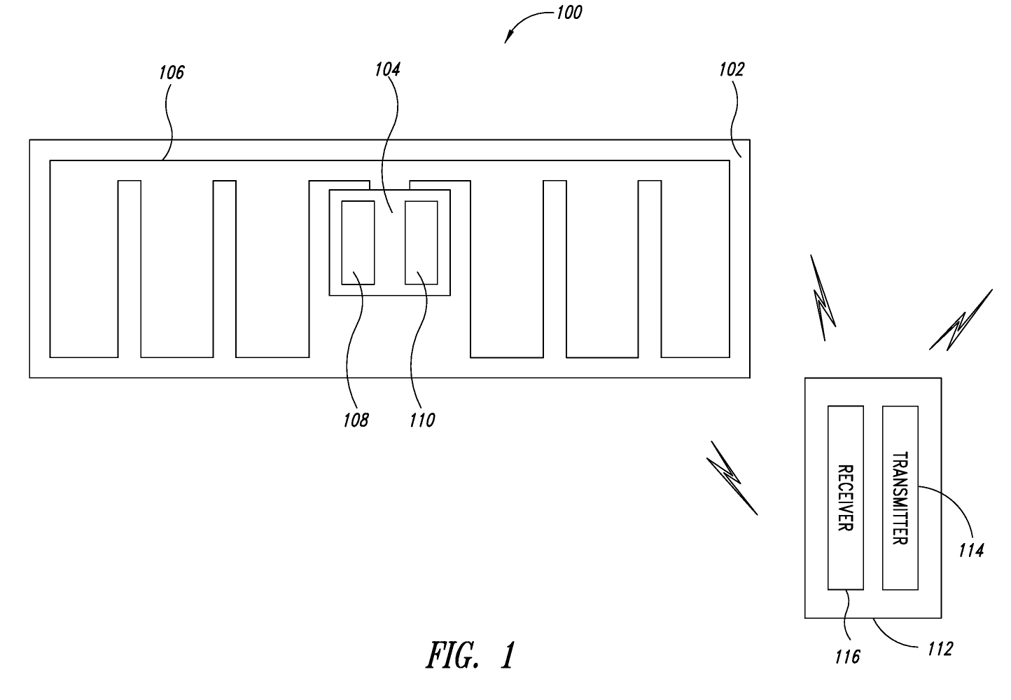

Referring to FIG. 1, a typical RFID tag 100 is shown. The tag 100 includes a substrate 102 which carries a circuit 104 and an antenna 106. The antenna 106 is typically formed by conductive trace or pattern. The circuit 104 may take the form of a chip or other integrated circuit device, and may or may not be encapsulated. The circuit 104 may be formed directly on the substrate, or may be mounted thereto, such as by surface mounting. The circuit 104 typically includes a memory 108 and may also include or implement logic 110. Some RFID tags include a discrete power source such as battery. Others are passive, deriving power from a radio-frequency interrogation signal, as described below. RFID tags are produced in a wide variety of sizes and configurations. In some embodiments, the memory 108 is read-only, while in others the memory 108 is write or write/erase enabled.

A reader 112 is also shown in FIG. 1. The reader 112 includes a transmitter 114 and receiver 116, and is configured to transmit a radio-frequency interrogation signal and receive a responding signal from the tag 100. The reader 112 is shown diagrammatically as a single unit for descriptive purposes, but may comprise separate units housing the transmitter 114 and receiver 116, respectively. Alternatively, the transmitter 114 and receiver 116 may be formed as a transceiver. Additionally, many of the operations attributed to the reader 110 in the description below may be performed by separate components such as a central control unit or other dedicated equipment.

When the RFID tag 100 is brought within range of the RFID reader 112, the antenna 106 receives an electromagnetic signal from the transmitter 114. In the case of a passive system, the signal induces sufficient current in the antenna 106 to activate the circuit 104. Additionally, the signal may be modulated to carry various data, instructions and/or access codes to the circuit 104. The circuit 104 then transmits a response to the reader 112, which is detected by the receiver 116. For example, the reader 112 may access the memory 108 of the RFID tag 100 to determine the unique identity of the tag 100, or to access other information in the memory 108. Additionally, in cases where the RFID tag 100 is so configured, data may be written to the memory 108 for future use. The logic 110 supports the operation of the memory 108, and manages communication with the reader 112. These characteristics of an RFID system allow its employment in applications that are much broader than simple detection, such as is the most common application of EAS systems.

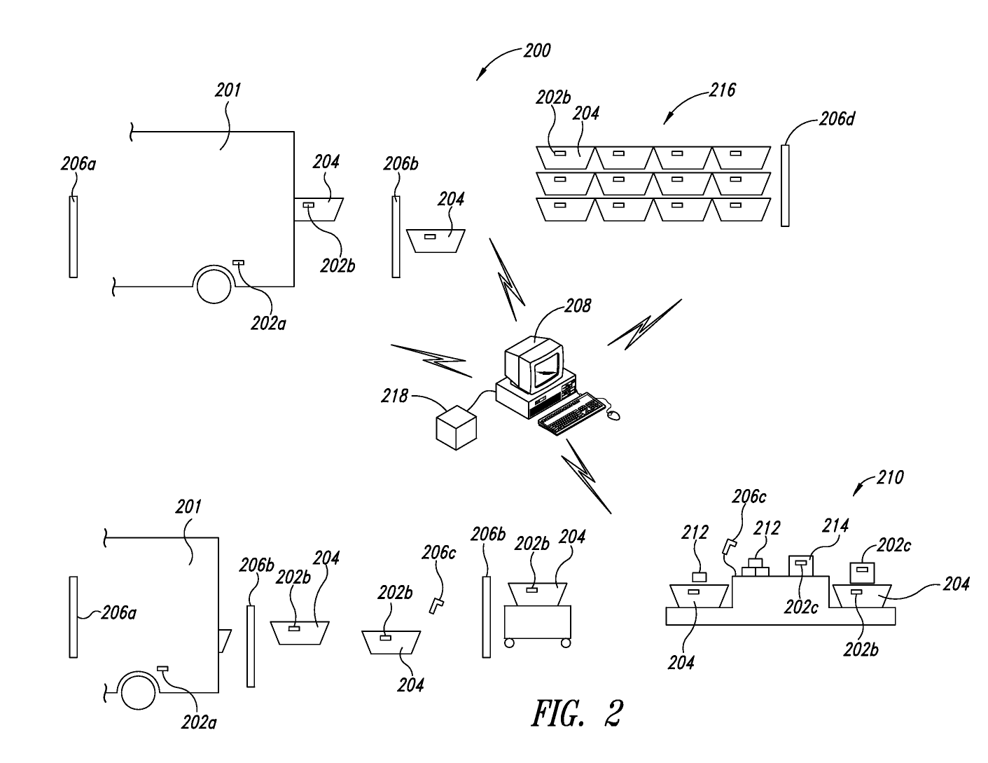

FIG. 2 shows an RFID system according to an illustrated embodiment. The system includes RFID tags 202 and readers 206 that may or may not be similar in operation to the tag 100 and reader 110 described with reference to FIG. 1. Thus each tag 202 or reader 206 may include any or all of the components or functionality previously described, or may have other features that such devices are known in the art to have. The tags 202 and readers 206 are further designated with letters to indicate different applications or configurations, but these designations are for the purpose of this exemplary description, only, and do not limit the scope of the invention. Reference to a tag 202 or reader 206 without a letter designator may be considered a more general reference to such a device, without regard to its particular application.

FIG. 2 depicts a generic manufacturing facility 200. A simplified operation is described with reference thereto.

A cargo vehicle 201 arrives at a receiving dock of the facility 200. The vehicle 201 is provided with an RFID tag 202a, which has been programmed with information such as a unique identifier for the vehicle, the vehicle departure point and time, and contents of the vehicle 201. Upon arrival at the facility 200, the vehicle 201 passes a reader 206a, which notes the information on the vehicle's tag 202a and transmits the information to a central processor 208.

The contents of the vehicle 201 are contained in reusable containers 204, each provided with an RFID tag 202b. As the containers 204 are removed from the vehicle 201, they pass an RFID reader 206b, which interrogates the RFID tag 202b of each container 204 as it passes, and obtains information such as the contents and shipping history of the respective container 204. This information is transmitted to the central processor 208, which determines the appropriate destination of the respective container 204 and transmits routing instructions back to the reader 206b. The routing instructions are stored in the memory of the respective RFID tag 202b and the container 204 is appropriately routed.

Handlers at the facility 200 may be provided with hand-held RFID readers 206c to enable them to download information from the tags 202b thereon to obtain routing information, for example. Additionally, RFID readers 206d may be provided at various locations in the facility to track the movement of each of the containers 204 and confirm their locations.

The facility 200 includes assembly stations 210 where products are assembled. An operator at an assembly station 210 uses a hand-held reader 206c to log the arrival of a container 204 and verify its contents. The container 204 is then opened, and components 212 are removed for installation in a final product 214. The final product 214 is provided with an RFID tag 202c programmed by the operator with information such as the date of manufacture, the source of the components 212 used in its assembly, the operator, the assembly station, model number, serial number, etc. This information remains with the product 214 through distribution or in some cases for the life of the product, and can be accessed at any time thereafter. Additionally, more information may be stored on the same RFID tag 202c, such as handling and transport of the product 214 after manufacture, date and location of sale of the product, purchaser of the product, etc.

Following assembly, the operator places the product 214 into another container 204, bearing a tag 202b that is written with information identifying the contents thereof. The container 204 holding the finished product 214 is then appropriately routed for storage or delivery. As containers 204 are moved into and out of warehousing or staging 216, an RFID reader 206d records the arrival and contents of each container 204, transmitting that information to the central processor 208.

Finally, as containers 204 are loaded onto a cargo vehicle 201, the information stored on each of their RFID tags 202b is read and transmitted to the central processor 208. As the vehicle 201 departs, it passes a reader 206a, which programs the vehicle's RFID tag 202a with the contents thereof, date and place of departure, etc.

Information from the RFID readers 206 throughout the facility 200 may be transmitted to the central processor 208 by any of several methods, including, for example, wireless connection, dedicated data cables, telephone lines, web based connection, etc.

A monitor module 218 is configured to track interrogation signals transmitted by RFID readers 206. In particular, the monitor module 218 is configured to monitor transmission pulse frequencies of the readers 206. Operation of the monitor module 218 will be described in more detail below. The module is shown in the diagram of FIG. 2 as a stand-alone-device, but this is for illustration only, and does not limit the composition or configuration of the module.

While the description provided above is merely exemplary, it may be seen that RFID systems can be extremely useful in many industrial applications and settings, providing extremely accurate and detailed information regarding a wide range of operational details, and that a typical industrial application may employ a large number of RFID readers therein. Additionally, it may be seen that such systems have wide applicability, beyond the industrial type application described herein.

The inventor is unaware of any studies or reports indicating interference by RFID systems with ICD's like the interference discussed in the background section of the present disclosure with reference to EAS systems. Additionally, RFID systems have not been thought to pose any particular danger to ICD's, inasmuch as RFID systems operate at frequencies ranging, generally, between 500 and 5,000 MHz, while, as discussed above, implantable devices are sensitive to frequencies ranging well below 100 Hz. Nevertheless, the inventor has determined that there may be some potential for concern, as detailed hereafter.

In a facility incorporating a number of RFID readers, there is a potential for interference between readers, as transmission from one reader may interfere with reception of anther reader nearby, for example. In order to avoid such a problem, all the readers of the facility, or of a zone of the facility, may be programmed to operate sequentially. In other words, each reader in turn may operate for a few milliseconds, then stop transmitting while the next reader in the sequence operates. Thus each reader produces signal pulses (also referred to as interrogation pulses or transmission pulses) at a rate that is determined, in part, by the number of readers in the sequence. As the number of readers increases, the frequency of pulses emitted by any one of the readers decreases correspondingly.

Additionally, some jurisdictions in which RFID systems are employed impose limits on transmission time of devices that produce electromagnetic energy. Typically this is expressed in terms of a maximum duty cycle at which such systems can operate. Thus, if the maximum duty cycle is, for example, 20%, an RFID system operating under such a restriction must refrain from transmitting for 80% of the time.

Another consideration is the minimum acquisition time. This is the minimum amount of time required for a reader to transmit a signal of sufficient duration to activate an RFID tag within range, for the tag to activate and respond, for the reader to detect the response and identify the tag, and, in cases where the tag is writable, to write data to the tag. Thus, the duration of each transmission pulse of a reader must be at least equal to the minimum acquisition time, referred to hereafter as a minimum-time pulse.

In accordance with the duty-cycle requirements of the example outlined above, one method of operation includes pulsing each of the readers of a system one time, in sequence, with time T being equal to the time required to cycle once through each of the readers. The system then pauses for a time period equal to 4T, resulting in a total duration for a single cycle of 5T. The system continues alternating the cycled reading pulses and the pauses. In this way, a 20% duty cycle is achieved.

It will be recognized, however, that the pulse frequency of any one of the RFID readers in the sequence is determined by the cycle period, or the period of time required to cycle through all the readers, plus the pause time. If, for example, the total time required to cycle through all of the readers is 20 milliseconds, then the following pause will be 80 milliseconds. In that case, the cycle period will be 100 milliseconds, and the pulse rate or frequency will be 10 Hz. This frequency falls within the detection range of a typical implantable defibrillator, and so might be found to interfere with the operation of an ICD.

Another reason that the inventor considers the issue to be of some concern is that, in the case of RFID readers in applications such as that described with reference to FIG. 2, the possibility that an individual having an ICD might stand for an extended period of time near one of the readers 204 is very high, due to the large number of readers and their placement throughout such a facility.

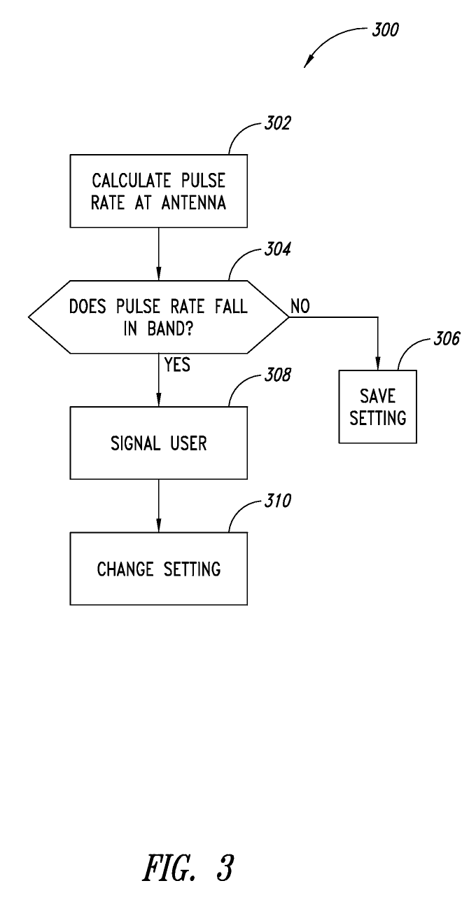

FIG. 3 is a flow chart illustrating a general method 300, according to an illustrated embodiment. An RFID system, such as the system 200 described with reference to FIG. 2, is provided with a monitor module 218 configured to calculate, during system set-up, the signal pulse rate of each reader 206 of the system 200, as indicated in block 302. If the calculated rate does not fall within a selected frequency band (block 304, NO path), the settings are enabled and saved (block 306). If the calculation indicates that one or more of the reader pulse frequencies does fall within the selected band (block 308, YES path), the user is notified (308) and prompted to change system settings (block 310), as described in more detail hereafter.

In some cases, when an RFID system 200 is installed or modified, the user selects operating parameters such as operating frequency, duty cycle, number of readers, transmission pulse length, order of reader pulses, etc. According to one embodiment outlined above, the monitor module 218 is associated with the central processor 218 of the RFID system 200. It may be incorporated as a software module in the software controlling the system 200, or may be a stand-alone program or device, or as a hardwired circuit. The settings of the module 218 may be user adjustable, and may be subject to user override.

As the user configures the RFID system 200, the monitor module 218 calculates the pulse frequency of each of the readers 206 of the RFID system 200. If the calculated pulse frequency of any of the readers 206 falls within a selected band of frequencies, such as might be likely to interfere with the operation of an ICD, for example, the monitor module 218 alerts the user, who can then take steps to modify the pulse frequency. There are several possible changes that a user can make in the operating parameters of the RFID system 200 that will affect the pulse frequency.

For example, If the selected transmission pulse length is longer than a minimum-time pulse length, the transmission pulse length may be shortened, resulting in a shortened cycle period and therefore a higher pulse rate; if the duty cycle is increased, this will shorten the pause between transmission pulses, which, too will increase the pulse rate; and the user may divide the RFID readers 206 of the RFID system 200 into two or more zones, resulting in fewer RFID readers per zone and a consequent increased pulse rate.

The RFID system 200 may have the flexibility to vary the length of the transmission pulses such that, if no RFID tag 202 is detected during a selected fraction of the minimum-time pulse, the pulse is terminated early. In this arrangement, only those readers 206 that are actually interrogating an RFID tag 202 will transmit for the full transmission pulse length, which will shorten the overall cycle period, but will reduce the predictability of the average pulse rate.

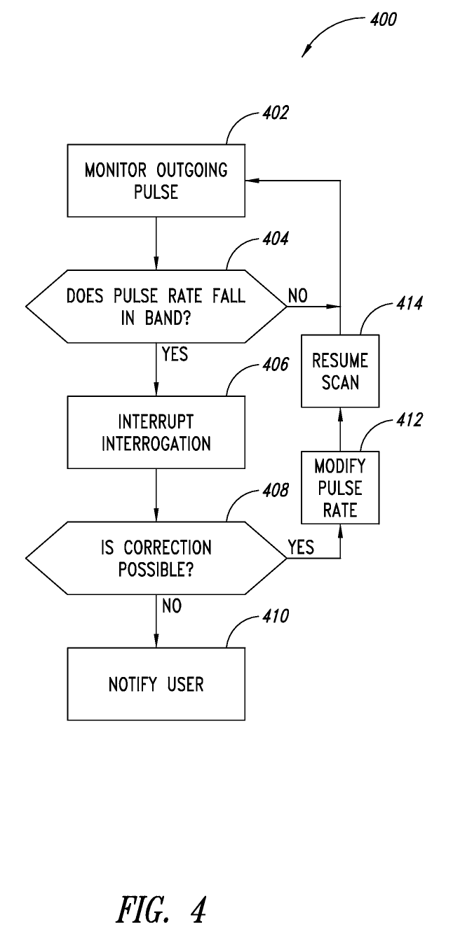

FIG. 4 is a flow chart illustrating a general method 400, according to another embodiment of the invention. An RFID reader 206 is provided with a monitor module 218 configured to monitor its signal pulse rate, as indicated in block 402. While the pulse rate remains outside a selected frequency band, no action is taken (block 402, NO path). If the pulse rate falls within the selected frequency band (block 404, YES path), transmission is interrupted (block 406), and correction is attempted (block 408), as described in more detail hereafter. If correction is not possible (408, NO path), the user is notified (410), and operation is discontinued pending action by the user. If correction is possible (408, YES path) the pulse frequency is modified (block 412) and scan is resumed (414).

The monitor module 218 of the embodiment of FIG. 4 may be incorporated into an individual RFID reader 206 or into the central processor 208 and configured to monitor each of the readers 206 of the RFID system 200.

In addition to the methods outlined above for modifying the pulse rate, the rate can also be modified at an individual RFID reader 206, as necessary. As explained above, most ICD's are configured to monitor an abnormal beat pattern for a period of time before initiating corrective action. However, if the beat pattern normalizes during that period, the ICD's counter resets. Accordingly, if the monitor module 218 detects a pulse rate that falls within a range of frequencies that might interfere with an ICD, interrogation pulses may be interrupted for a period sufficient to allow an ICD to reset, then resume transmission.

In such a case it would be necessary to determine how long passing RFID tags 202 will normally be within the effective radius of the RFID reader 206, to ensure that the RFID tag 202 will be within range for longer than the interruption period. For example, this may not be the best solution in the case of RFID readers 206a, positioned and tasked for reading RFID tags 202a affixed to passing motor vehicles 201, inasmuch as a vehicle passing during the interruption might not be detected. On the other hand, it may be possible to position such an RFID reader 206a in a location where it would be unlikely that any individual would have a need to stand close to the RFID reader 206a for any length of time, which would reduce the likelihood of ICD interference.

Another method is to emit a single electromagnetic spike approximately midway between two interrogation pulses and timed to occur between transmissions of other RFID readers 206 in a given zone, or during the off portion of the duty cycle. As a single spike, the duration can be vanishingly short, so it will not add substantially to the total length of the cycle, but an ICD device will note the spike as a separate signal pulse, which will effectively double the detected pulse rate. This method may be applied in either of the embodiments outlined above.

If necessary to raise the detected pulse rate above a threshold, additional electromagnetic spikes, such as described above, may be emitted.

Details of circuits or programs configured to carry out the processes outlined in the embodiments described above have not been provided, inasmuch as it is within the abilities of one of ordinary skill in the art to design such circuits or programs to for this purpose.

Embodiments of the invention have been described with reference to RFID systems. Nevertheless, it will be recognized that various aspects of the invention may be applied with advantage to the operation of other classes of devices, such as, for example, EAS systems, cellular telephone systems, remote control devices, and other consumer or industrial electronic devices. Accordingly, such applications are considered to fall within the scope of the invention.

As used in the present disclosure and claims, the term “operating frequency” refers to the frequency at which a device transmits and/or receives data or energy, and may be used in reference to an analog or digital signal, with or without modulation. Terms such as “interrogation pulse,” “signal pulse,” and “transmission pulse” are used interchangeably to refer to a transmission at the operating frequency for a definable period. Typically, a string of one or more transmission pulses is followed by an off-period during which there is no transmission. A duty cycle is defined by a ratio of a transmission pulse string length relative to a length of the sum of the transmission pulse string length and an off-period immediately following. “Pulse frequency” and “pulse rate” are used interchangeably to refer to a frequency of a pulsed signal at which transmission pulses are emitted by the device. Cycle period refers to the length of the sum of a single pulse string length and a succeeding off-period in a pulsed signal.

As used in the claims, the terms “interrogation pulse” or “transmission pulse” may also refer to a signal produced by an EAS transmitter for the purpose of detecting an EAS tag.

The above description of illustrated embodiments, including what is described in the Abstract, is not intended to be exhaustive or to limit the invention to the precise forms disclosed. Although specific embodiments and examples are described herein for illustrative purposes, various equivalent modifications can be made without departing from the spirit and scope of the invention, as will be recognized by those skilled in the relevant art. The teachings provided herein can employ other automatic data collection or security systems, not necessarily the exemplary RFID system generally described above.

For instance, the foregoing detailed description has set forth various embodiments of the devices and/or processes via the use of block diagrams, schematics, and examples. Insofar as such block diagrams, schematics, and examples contain one or more functions and/or operations, it will be understood by those skilled in the art that each function and/or operation within such block diagrams, flowcharts, or examples can be implemented, individually and/or collectively, by a wide range of hardware, software, firmware, or virtually any combination thereof. In one embodiment, the present subject matter may be implemented via Application Specific Integrated Circuits (ASICs). However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A radio frequency identification (RFID) system, comprising:
an RFID tag reader configured to interrogate RFID tags in transmission pulses, each of the pulses including a plurality of signal cycles at an operating frequency; and
a monitor module configured to monitor a transmission pulse rate of the RFID tag reader and detect a pulse rate falling within a selected frequency range.

2. The system of claim 1 wherein the monitor module is configured to modify the pulse rate to produce a transmission pulse rate that does not fall within the selected frequency range.

3. The system of claim 1 wherein the monitor module is configured to interrupt operation of the RFID system upon detection of a pulse rate falling within the selected frequency range.

4. The system of claim 1 wherein the monitor module is configured to signal a user upon detection of a pulse rate falling within the selected frequency range.

5. The system of claim 1 wherein the RFID tag reader is configured to read and write data to RFID tags

6. The system of claim 1 wherein the RFID tag reader is configured to transmit at a duty cycle below a threshold duty cycle.

7. The system of claim 1 wherein the RFID system comprises a plurality of RFID tag readers, including the RFID tag reader, the plurality of RFID tag readers configured to interrogate RFID tags sequentially.

8. The system of claim 7 wherein the transmission pulse rate of the RFID tag reader is a rate of pulses sent to a single one of the plurality of RFID tag readers.

9. The system of claim 7 wherein the transmission pulse rate is equal to a total pulse rate of the RFID system, divided by the number of the plurality of RFID tag readers.

10. The system of claim 1 wherein the monitor module is a software module of a controller of the RFID system.

11. An electronic device, comprising:
a component capable of emitting an electromagnetic signal;
detecting means for detecting a pulse frequency of the electromagnetic signal; and
mitigating means for mitigating interference of the electromagnetic signal with an implantable cardiac device.

12. The device of claim 11 wherein the electronic device is a radio frequency identification device.

13. The device of claim 11 wherein the mitigating means comprises means for modifying the electromagnetic signal.

14. The device of claim 11 wherein the mitigating means includes means for interrupting emission of the electromagnetic signal.

15. The device of claim 11 wherein the detecting means comprises means for identifying a pulse frequency that falls within a range of frequencies.

16. A method of mitigating interference, the method comprising:
periodically transmitting an interrogation pulse;
determining a length of a period of the periodically transmitting act;
determining whether the length of the period falls within a selected range; and
if the length of the period is determined to fall within the selected range, modifying a succeeding period to fall outside the selected range.

17. The method of claim 17 wherein the modifying act comprises transmitting an electromagnetic spike between transmission of two consecutive interrogation pulses.

18. The method of claim 17 wherein the modifying act comprises shortening the succeeding period.

19. The method of claim 17 wherein the interrogation pulse is a radio frequency identification interrogation pulse.

20. The method of claim 17 wherein the interrogation pulse is an electronic article surveillance interrogation pulse.

21. A method of mitigating interference with a medical device, the method comprising:
selecting operating parameters of a transmitter;
calculating a transmission pulse rate of the transmitter based on the selected parameters; and
generating an alert signal if the calculated transmission pulse rate falls within a range of frequencies.

22. The method of claim 22 wherein the selected parameters include one or more of a number of transmitters, a transmission duty cycle, and a transmission pulse length.

23. The method of claim 22 wherein the transmitter is a radio frequency identification transmitter.

24. The method of claim 22 wherein the transmitter is an article surveillance system transmitter.
